(19) United States
(12) Patent Application Publication
(10) Pub. No.: US 2024/0105585 A1
(43) Pub. Date: Mar. 28, 2024

(54) SOLID STATE ELECTROLYTES FOR BACKEND SUPERCAPACITORS

(71) Applicant: Intel Corporation, Santa Clara, CA (US)

(72) Inventors: Abhishek Anil Sharma, Portland, OR (US); Pushkar Ranade, San Jose, CA (US); Tahir Ghani, Portland, OR (US); Wilfred Gomes, Portland, OR (US); Sagar Suthram, Portland, OR (US); Anand Murthy, Portland, OR (US)

(73) Assignee: Intel Corporation, Santa Clara, CA (US)

(21) Appl. No.: 17/955,245

(22) Filed: Sep. 28, 2022

(51) Int. Cl. H01L 23/522; H01L 23/427

(52) U.S. Cl. CPC H01L 23/5223; H01L 23/427

(57) ABSTRACT

An embodiment of a capacitor in the back-side layers of an IC die may comprise any type of solid-state electrolyte material disposed between electrodes of the capacitor. Another embodiment of a capacitor anywhere in an IC die may include one or more materials selected from the group of indium oxide, indium nitride, gallium oxide, gallium nitride, zinc oxide, zinc nitride, tungsten oxide, tungsten nitride, tin oxide, tin nitride, nickel oxide, nickel nitride, niobium oxide, niobium nitride, cobalt oxide, and cobalt nitride between electrodes of the capacitor. Other embodiments are disclosed and claimed.

### BACKGROUND

An integrated circuit may include a variety of capacitors. There is an ongoing need for improved computational devices to enable ever increasing demand for modeling complex systems, providing reduced computation times, and other considerations. In some contexts, scaling features of integrated circuits has been a driving force for such improvements. Other advancements have been made in materials, device structure, circuit layout, and so on. In particular, there is an ongoing desire to improve capacitor device structures that are included in or otherwise support operation of integrated circuits. It is with respect to these and other considerations that the present improvements have been needed. Such improvements may become critical as the desire to improve computational efficiency become even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIG. 1 illustrates a block diagram side view of an example integrated circuit (IC) die;

FIG. 2 illustrates a block diagram side view of another example IC die;

FIG. 3 illustrates a block diagram of an example of a system;

FIGS. 4A to 4B illustrate cross sectional side views of example solid state electrolyte (SSE) capacitors;

FIGS. 5A to 5C illustrate cross sectional side views of other example SSE capacitors;

FIG. 6 illustrates a cross sectional side views of another example IC die with backend SSE metal-insulator-metal (MIM) decoupling capacitors;

FIG. 7 illustrates a cross-sectional view of a low-temperature IC system with SSE capacitors, using die- and package-level active cooling;

FIG. 8 illustrates a view of an example two-phase immersion cooling system for low-temperature operation of an IC die;

FIGS. 9A and 9B illustrates various processes or methods for forming SSE capacitors on an IC die;

FIG. 10 illustrates a diagram of an example data server machine employing an IC die with SSE capacitors; and

FIG. 11 is a block diagram of an example computing device, all in accordance with at least some implementations of the present disclosure.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure. The term “aligned” (i.e., vertically or laterally) indicates at least a portion of the components are aligned in the pertinent direction while “fully aligned” indicates an entirety of the components are aligned in the pertinent direction.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking, or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve capacitors in integrated circuit (IC) devices. Metal-insulator-metal (MIM) capacitors may be utilized as decoupling capacitors to help regulate power delivery to support the operation of an IC device. Such MIM capacitors first need to be charged and then the MIM capacitors discharge during droop events. A problem is that some capacitor materials may have relatively low (e.g., <500 nF/mm²) charge cap density. Power requirements for increasingly complex IC devices may benefit from better performance. Some solid-state electrolyte (SSE) materials may have better charge cap density characteristics. A problem is that some SSE materials may have reliability concerns because dendrite formation due to ion migration at room temperatures may cause the capacitor to fail. Some embodiments may overcome one or more of the foregoing problems. Some embodiments may include SSE materials for a MIM capacitor. Some embodiments may include SSE materials for a backend supercapacitor. Advantageously, embodiments of an SSE capacitor may utilize SSE material as MIM electrolytes for improved charge density (e.g., >5000 nF/mm²). In some embodiments, a MIM SSE capacitor may advantageously provide surge currents during low temperature operation without failing due to dendrites.

IC dies, systems, circuits, and techniques are described herein may also relate to SSE capacitor devices for ultra-low voltage operation. Such SSE capacitor devices may be operable at very low temperatures for improved device performance and/or they may be integrated with complementary metal oxide semiconductor field effect transistors (CMOS FETs) such as FinFETs.

Techniques discussed herein provide advantageous SSE capacitor devices for low voltage applications. In some embodiments, such applications are deployed at very low temperatures, such as, at or below 0° C. For example, the SSE capacitor devices may be deployed in an IC die including or coupled to cooling structure operable to remove heat from the IC die to achieve an operating temperature at the very low temperature. As used herein, the term cooling structure or active cooling structure indicates a device that uses power to provide cooling (e.g., via flow of a coolant, immersion in a coolant, etc.). Notably, the cooling structure or active cooling structure need not be in operation to be labeled as such. The active cooling structure may be part of the IC die, provided separate from the IC die, or both. In some contexts, an active cooling structure is not needed as the IC die is deployed in a very low temperature environment such as in any of a subpolar oceanic climate, a subarctic climate, an arctic climate, a tundra climate, an ice cap climate, or any other environment of sustained cold temperatures.

In some embodiments, an SSE capacitor device includes inorganic solid electrolyte (SE) materials. At room temperatures, such materials do not exhibit high capacitance and are subject to dendrite formation. However, at very low temperatures, such materials exhibit higher capacitance characteristics and dendrite formation is more inhibited.

In deployment at very low temperatures, SSE capacitor devices using such materials systems have suitable capacitor behavior and reliability. Therefore, such SSE capacitor devices may advantageously be deployed as various circuits/devices including decoupling capacitors, etc. In some embodiments, the SSE capacitor devices are used as decoupling capacitors at very low voltage. In some implementations, the term very low voltage indicates a voltage of not more than 50 mV, although lower voltages may be used such as voltages of not more than 10 mV. In some embodiments, the SSE capacitor devices are integrated with CMOS FETs such as CMOS FinFETs. Notably, after fabrication of the SSE capacitor devices over a first substrate, the SSE capacitor devices may be layer transferred to a second substrate such as a silicon substrate and the CMOS FETs may be fabricated in an exposed portion of the silicon substrate either on the same side as the SSE capacitor devices or on an opposite side of the SSE capacitor devices. The SSE capacitor devices and CMOS FETs are then integrated into circuits that advantageously use both transistor types at very low temperature. For example, the SSE capacitor devices may be deployed as decoupling capacitors, etc., and the CMOS FETs may be deployed in other circuitry.

As discussed, an IC die including SSE capacitor devices and CMOS FETs may be deployed in a very low temperature context. In some embodiments, the operating temperature of the IC die is maintained at or below 0° C. In some embodiments, the operating temperature of the IC die is maintained at or below about −196° C. (i.e., using liquid nitrogen as the coolant). In some embodiments, the operating temperature of the IC die is maintained at or below about −25° C. In some embodiments, the operating temperature of the IC die is maintained at or below about −50° C. In some embodiments, the operating temperature of the IC die is maintained at or below about −70° C. In some embodiments, the IC die is maintained at or below about −100° C. Other temperatures may be used based on coolant, environment, and so on. Other temperatures may be used based on coolant, environment, and so on. In operation at such very low temperatures, the SSE capacitor devices become operable and the CMOS FETs see a substantial boost in performance relative to operation at higher temperatures inclusive of increased carrier mobility, reduced contact resistance, and reduced leakage.

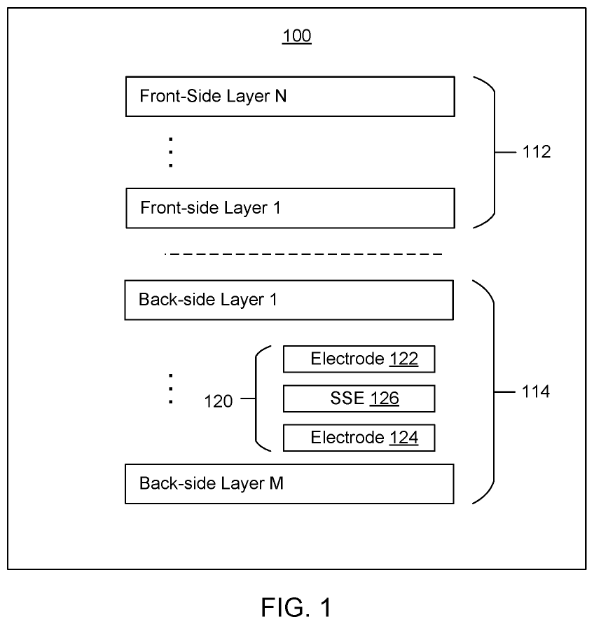

FIG. 1 shows an illustrative block diagram side view of an example integrated circuit (IC) die 100 that includes SSE capacitors in accordance with some embodiments. The IC die 100 includes front-side layers 112, back-side layers 114 coupled to the front-side layers 112, and a capacitor 120 in the back-side layers 114. The capacitor 120 may comprise a first electrode 122, a second electrode 124, and SSE material 126 disposed between the first electrode 122 and the second electrode 124. In some embodiments, the SSE material 126 may comprise an inorganic solid electrolyte (SE) material. For example, the inorganic SE material may comprise one or more materials selected from the group of indium oxide, indium nitride, gallium oxide, gallium nitride, zinc oxide, zinc nitride, tungsten oxide, tungsten nitride, tin oxide, tin nitride, nickel oxide, nickel nitride, niobium oxide, niobium nitride, cobalt oxide, and cobalt nitride.

In some embodiments, the capacitor 120 in the back-side layers 114 may comprise a decoupling capacitor. For example, the decoupling capacitor may comprise a metal-insulator-metal (MIM) decoupling capacitor. In some embodiments, the capacitor 120 in the back-side layers 114 may comprise a supercapacitor. In some embodiments, the capacitor 120 in the back-side layers 114 may comprise an SSE battery. The illustrated capacitor 120 has a horizontal orientation, but the capacitor 120 may have any useful structure and orientation (e.g., a vertical orientation). Non-limiting examples of SSE capacitor structures include flat plate capacitors, cylindrical capacitors, corrugated capacitors, trench capacitors, and interdigitated electrode capacitors, each of which may utilize the SSE material 126 as described herein between the various electrode structures. The IC die 100 may include multiple SSE capacitors, including one or more additional SSE capacitors in the back-side layers 114 and one or more additional SSE capacitors in the front-side layers 112.

In some embodiments, the IC die 100 may further include a plurality of microchannels in the IC die 100 and over the front-side and back-side layers 112, 114, the microchannels to convey a heat transfer fluid therein. In some implementations, the IC die 100 may be thermally coupled to a cooling structure operable to remove heat from the IC die 100 to achieve an operating temperature at or below −25° C.

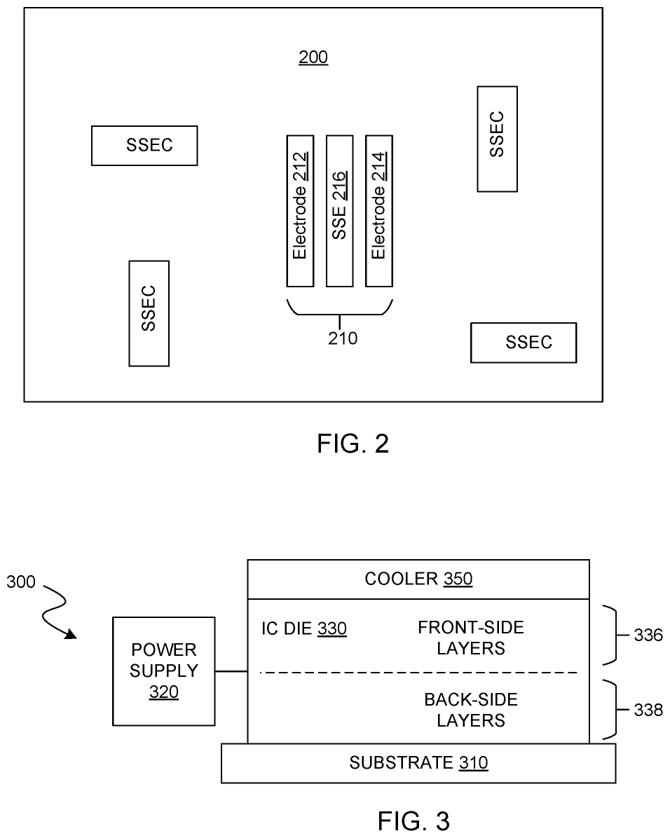

FIG. 2 shows an illustrative block diagram side view of an example IC die 200 that includes SSE capacitors in accordance with some embodiments. The IC die 200 includes a plurality of capacitor devices (e.g., labeled as SSE capacitor), where at least one capacitor 210 of the plurality of capacitor devices comprises a first electrode 212, a second electrode 214, and SSE material 216 disposed between the first electrode 212 and the second electrode 214, where the SSE material 216 comprises one or more materials selected from the group of indium oxide, indium nitride, gallium oxide, gallium nitride, zinc oxide, zinc nitride, tungsten oxide, tungsten nitride, tin oxide, tin nitride, nickel oxide, nickel nitride, niobium oxide, niobium nitride, cobalt oxide, and cobalt nitride. The capacitor 210 may be located anywhere in the IC die 200. In some embodiments, the IC die 200 may include front-side layers and back-side layers coupled to the front-side layers, and the capacitor 210 may be in the front-side layers or back-side layers. For example, the capacitor 210 may comprise a decoupling capacitor (e.g., a MIM decoupling capacitor), a supercapacitor, an SSE battery, etc.

The illustrated capacitor 210 has a vertical orientation, but the capacitor 210 may have any useful structure and orientation (e.g., a horizontal orientation). Non-limiting examples of SSE capacitor structures include flat plate capacitors, cylindrical capacitors, corrugated capacitors, trench capacitors, and interdigitated electrode capacitors, each of which may utilize the SSE material 216 as described herein between the various electrode structures. The IC die 200 may include further SSE capacitors, including one or more additional SSE capacitors in the back-side layers and one or more additional SSE capacitors in the front-side layers.

In some embodiments, the IC die 200 may further include a plurality of microchannels in the IC die 200 and over the SSE capacitors, the microchannels to convey a heat transfer fluid therein. In some implementations, the IC die 200 may be thermally coupled to a cooling structure operable to remove heat from the IC die 200 to achieve an operating temperature at or below −25° C.

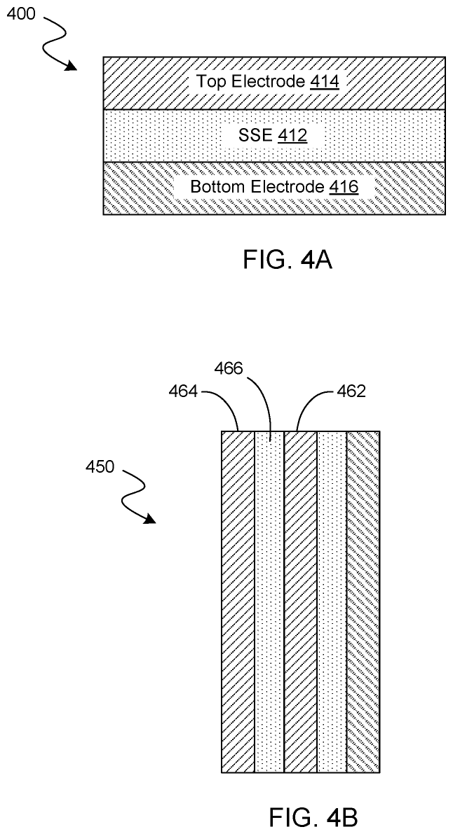

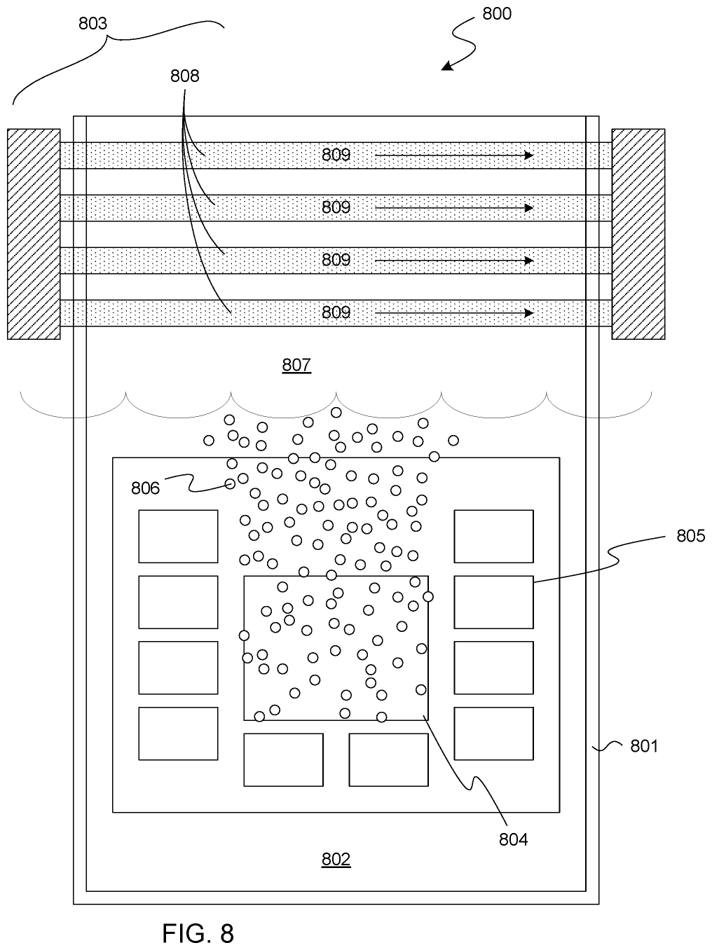

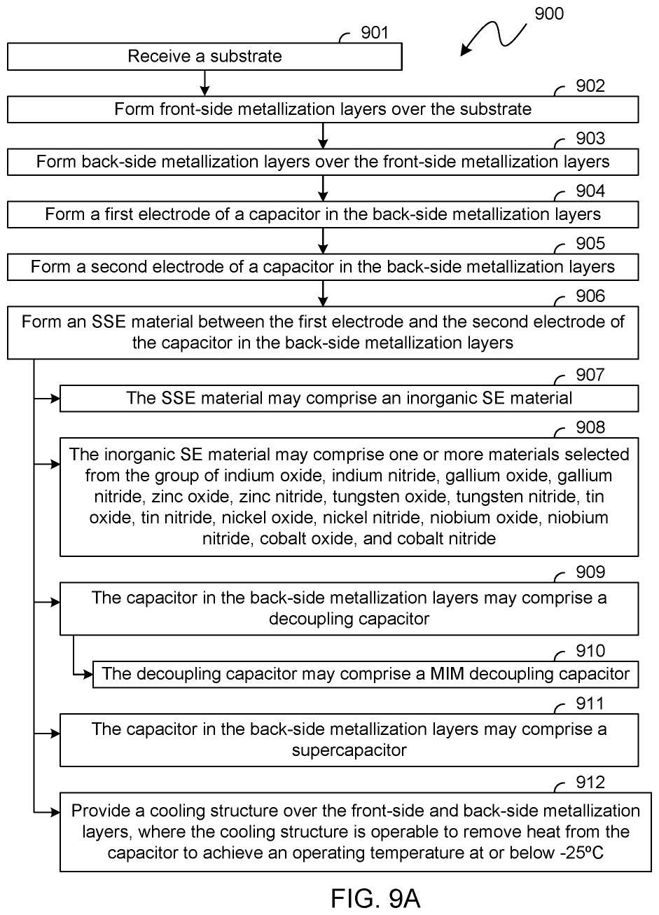

FIG. 3 shows a block diagram view of an example of a system 300 that includes a substrate 310, a power supply 320, and an IC die 330 attached to the substrate 310 and coupled to the power supply 320. The IC die 330 may be similarly configured as any of the various ICs described herein including, for example, the IC die 100 (FIG. 1), the IC die 200 (FIG. 2), and IC die 702 (FIG. 7). Any suitable substrate technology may be utilized for the substrate 310 including, for example, the substrates described herein in connection with FIGS. 7 and 8 (e.g., substrate 805). In some embodiments, the IC die 330 may be coupled to the power supply 320 through the substrate 310.

In some embodiments, the IC die 330 may comprise front-side layers 336, back-side layers 338 coupled to the front-side layers 336, and an SSE capacitor in the back-side layers 338. The SSE capacitor in the back-side layers 338 may comprise a first electrode, a second electrode, and SSE material disposed between the first electrode and the second electrode. In some embodiments, another SSE capacitor located anywhere in the IC die 330 may comprise an inorganic SE material between two electrodes. For example, the inorganic SE material comprises one or more materials selected from the group of indium oxide, indium nitride, gallium oxide, gallium nitride, zinc oxide, zinc nitride, tungsten oxide, tungsten nitride, tin oxide, tin nitride, nickel oxide, nickel nitride, niobium oxide, niobium nitride, cobalt oxide, and cobalt nitride. In some embodiments, the SSE capacitor in the back-side layers may comprise a decoupling capacitor (e.g., a MIM decoupling capacitor), a supercapacitor, an SSE battery, etc.

In some embodiments, the system 300 may further include a cooler 350 (e.g., a cooling structure) operable to remove heat from the IC die 330 to achieve an operating temperature at or below −25° C. For example, the IC die 330 may comprise a plurality of metallization layers over a front side of the SSE capacitor devices, the metallization layers to provide signal routing for the SSE capacitor devices, and the cooler 350 is over the plurality of metallization layers. In some embodiments, the cooler 350 may include a plurality of microchannels in the IC die 330 and over the plurality of metallization layers, the microchannels to convey a heat transfer fluid therein. In some embodiments, the cooler 350 may further include a chiller mounted to the IC die 330 over the microchannels, the chiller comprising one of a solid body comprising second microchannels to convey a second heat transfer fluid therein or a heat sink for immersion in a low-boiling point liquid. In some embodiments, the cooler 350 may be configured to convey liquid nitrogen to achieve an operating temperature at or below about −196° C.

Embodiments of an SSE capacitor may utilize any suitable materials for the electrodes and the SSE material between the electrodes. Non-limiting example materials for the electrodes (e.g., which may or may not be considered cathodes and anodes depending on their resulting chemical composition and configuration during operation) include: MₓO_{y} (M=V, Mn); MS₂ (M=V, Ti); Li₁₋ₓCo_{1-y}M_{y}O₂ (M=Ni, Mg, etc.); Li₁₋ₓMn_{1-y}M_{y}O₂ (M=Co, Cr, etc.); Li₁₋ₓMn_{2-y}M_{y}O₄ (M=Ni, Mg, etc.); polyanion compounds LiₓMPO₄ (M=Fe, Co, Mn), LiₓVOPO₄, LiVPO₄F; organic molecules quinone Li₄C₆O₆, lithium metal/alloys; lithiated carbons; Sn/Si-based alloys; 3d-metal oxides; metal hydrides/nitrides; and organic molecules terephthalate Li₂C₈H₄O₄. Non-limiting example SSE materials include inorganic solids, solid polymers, polymer gels, and hybrid systems. Solid electrolytes, polymer electrolytes, and gel electrolytes may be better suited for some IC fabrication processes, as compared to liquid electrolytes. Some embodiments may utilize amorphous polysilicon and single crystal compounds of one or more materials selected from the group of indium oxide, indium nitride, gallium oxide, gallium nitride, zinc oxide, zinc nitride, tungsten oxide, tungsten nitride, tin oxide, tin nitride, nickel oxide, nickel nitride, niobium oxide, niobium nitride, cobalt oxide, and cobalt nitride.

In some embodiments, SSE materials may be utilized in back-end MIM capacitors to provide extra boost in the charge that is used during the IC operation (e.g., especially during high current events because the SSE material helps provide extra charge for high density applications). Some embodiments may be beneficial for regular voltages and regular operating temperatures. Some embodiments may be particularly beneficial for low voltages and low operating temperatures.

Depending on the materials, an embodiment of an SSE capacitor may be utilized as either a super capacitor or an SSE battery. In addition to electron charge, a supercapacitor may provide extra charge provided by ionic charge. Some electrolyte materials may amplify the charge by two or three times for a given voltage. For example, zinc-based SSE materials may provide two times the charge, indium-based SSE material may provide three times the charge, gallium-based SSE material may provide three times the charge, etc.

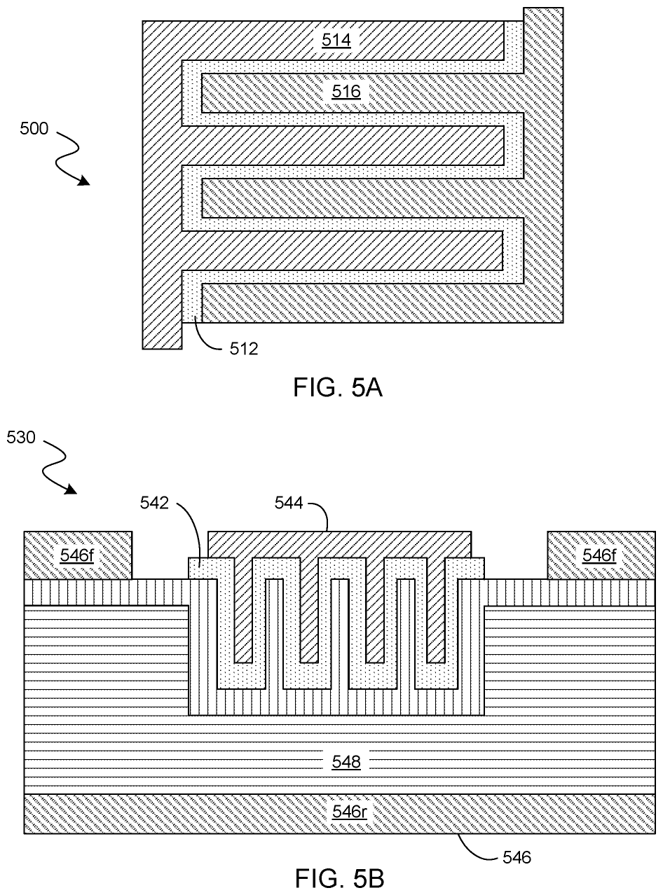

FIG. 4A illustrates a cross-sectional side view of an example of an SSE capacitor 400 that has a horizontal plate MIM structure. SSE material 412 is provided between a flat top electrode 414 and a flat bottom electrode 416.

FIG. 4B illustrates a cross-sectional side view of an example of an SSE capacitor 450 that has a general vertical cylindrical MIM structure. An inner cylindrical electrode 462 is surrounded an outer tubular electrode 464 with SSE material 466 therebetween.

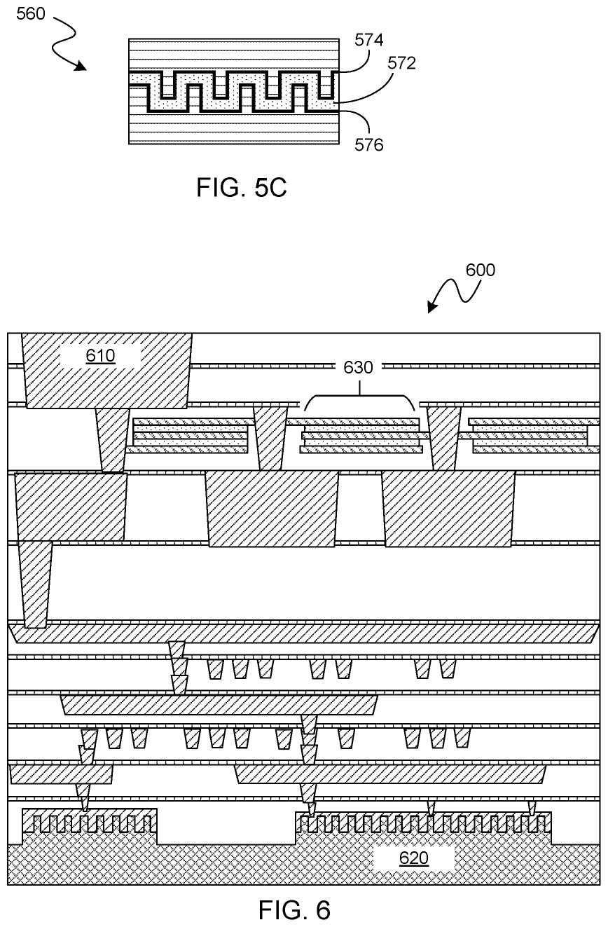

FIG. 5A illustrates a cross-sectional top view of an example of an SSE capacitor 500 that has an interdigitated structure. SSE material 512 is provided between a flat first electrode 514 and a flat second electrode 516. Each of the electrodes 514 and 516 have horizontally extended fingers, and the fingers interlock as shown. In some embodiments, layers of structures similar to electrodes 514, 516 may be stacked vertically with vertical metallization structures connecting the layers. Additional layers of SSE material may be alternated between the layers of interdigitated electrode fingers. With the stacked layers of interdigitated electrodes, the overall capacitance may include horizontal capacitance between the fingers in the layers and vertical capacitance between the layers.

FIG. 5B illustrates a cross-sectional side view an example of an SSE capacitor 530 that has a trench structure. SSE material 542 is provided between a top electrode 544 and a rear contact 546r of a bottom electrode 546. The bottom electrode 546 also includes front contact 546f. A trench capacitor may include deep narrow pores in a silicon substrate 548 to gain more surface and create a high-density capacitor saving die area. As illustrated, SSE material 542 is substituted for the dielectric material of the trench capacitor, advantageously increasing the capacitance density.

FIG. 5C illustrates a cross-sectional side view of an example of an SSE capacitor 560 that has a horizontal corrugated MIM structure. SSE material 572 is provided between a corrugated top electrode 574 and a corrugated bottom electrode 576.

Given the benefit of the present specification and drawings, those skilled in the art will appreciate that numerous other capacitor structures may beneficially substitute SSE material as described herein in between respective electrodes of the capacitor structures. A wide variety of capacitor structures may be more effective with the SSE material substituted for the dielectric of the capacitor structure. Some SSE capacitor structures may be even more effective at lower temperatures because the SSE materials may perform better at low temperatures.

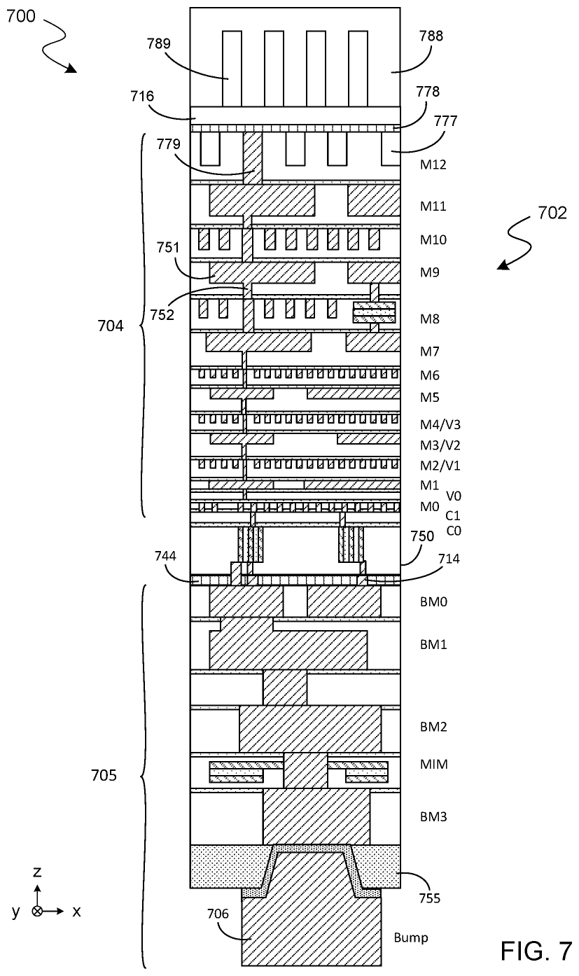

FIG. 6 illustrates a cross-sectional side view of an example of an IC die 600 that uses backend SSE MIM decoupling capacitors. Power is to be delivered to a contact pad 610 and through multiple metallization layers connected by vertical metallization structures (e.g., vias) to circuitry (e.g., buffers, repeaters, a core, etc.) in a substrate 620. MIM decoupling capacitors 630 are positioned close to the pad 610 and include SSE materials between the electrodes to improve power regulation in response to high current events. Although illustrated as flat plates, the SSE MIM decoupling capacitors 630 may have a corrugated top and bottom electrode structure.

In some embodiments, ICs with backend SSE capacitors may be integrated into a low-temperature system. Lower temperatures enhance conduction in many materials and can enable the use of, e.g., different materials and structures (such as smaller transistor channels). A number of structures may be used to lower the system temperature and so allow for the use of, e.g., smaller conducting structures. Active cooling structures can be used to lower system temperatures to below ambient temperature, even to well below ambient temperature. Active cooling structures can include thermoelectric coolers. In some embodiments, active cooling structures include stacks of alternating p- and n-type semiconductor materials. In some embodiments, active cooling structures flow cooling fluids through channels, including microchannels, thermally coupled to IC packages. In some embodiments, active cooling structures include channels thermally coupled to IC dies 100, 200, 330, 600. In some embodiments, active cooling structures include channels on one or more sides of IC dies 100, 200, 330, 600. In some embodiments, active cooling structures include channels within IC dies 100, 200, 330, 600. In some embodiments, active cooling structures include two-phase cooling. In some embodiments, active cooling structures include low-boiling-point fluids. In some embodiments, active cooling structures include refrigerants as cooling fluids. In some embodiments, active cooling structures lower system temperatures to below 0° C.

FIG. 7 illustrates a cross-sectional view of a low-temperature IC system 700 using die- and package-level active cooling, that includes backend SSE capacitors in accordance with some embodiments. In the example of IC system 700, IC die 702 includes active-cooling structures or components as provided by both die-level microchannels 777 and package-level active-cooling structure 788. IC system 700 includes a lateral surface along the x-y plane that may be defined or taken at any vertical position of IC system 700. The lateral surface of the x-y plane is orthogonal to a vertical or build-up dimension as defined by the z-axis. In some embodiments, IC system 700 may be formed from any substrate material suitable for the fabrication of transistor circuitry. In some embodiments, a semiconductor substrate is used to manufacture backend SSE capacitors and other transistors and components of IC system 700. The semiconductor substrate may include a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials, such as gallium arsenide. The substrate may also include semiconductor materials, metals, dielectrics, dopants, and other materials commonly found in semiconductor substrates.

In FIG. 7, IC system 700 includes an IC die 702, which is a monolithic IC with backend SSE capacitors as described herein, including front-side metallization layers 704 (or front-side interconnect layers), and optional back-side metallization layers 705 (or back-side interconnect layers). As shown, IC die 702 may include backend SSE capacitors in the back-side metallization layers 705 embedded between back-side metal layers BM2 and BM3. The IC die 702 may further include SSE capacitors within a dielectric layer 750 and in the front-side metallization layers 704 at front-side metal layer M8. (the detailed structure of the SSE capacitors is omitted from the cross-section of FIG. 7 to avoid obscuring the figure). In some embodiments, front-side metallization layers 704 (including further SSE capacitors) provide signal routing to the non-planar transistors and back-side metallization layers 705 provide power delivery, as enabled by through-contacts 714, and vias. In some embodiments, IC system 700 further includes a package-level cooling structure 788, which may be deployed on or over front-side metallization layers 704 (as shown) or on or over a back-side of IC die 702. In some embodiments, package-level cooling structure 788 is coupled to IC die 702 by an adhesion layer 716. IC system 700 may also be deployed without back-side metallization layers 705 shown in FIG. 7. In such embodiments, signal routing and power are provided to circuits of the IC die 702 via front-side metallization layers 704. However, use of back-side metallization layers 705 may offer advantages.

The circuits of the IC die 702 are connected and thermally coupled by metallization, e.g., metal heat spreader 744, to the entire metallization structure by through-contacts 714. In this way, circuits of the IC die 702 are thermally coupled to both the die-level active-cooling structures (of die-level microchannels 777) and package-level active-cooling structure 788.

Interconnectivity of transistors, signal routing to and from circuitry of the IC die 702, vias 752 (e.g., and other vias), etc., power delivery to circuitry of the IC die 702, etc., and routing to an outside device (not shown), is provided by front-side metallization layers 704, optional back-side metallization layers 705, and package-level interconnects 706. In the example of FIG. 7, package-level interconnects 706 are provided on or over a back-side of IC die 702 as bumps over a passivation layer 755, and IC system 700 is attached to a substrate (and coupled to signal routing to, power delivery, etc.) by package-level interconnects 706. However, package-level interconnects 706 may be provided using any suitable interconnect structures such as bond pads, solder bumps, etc. Furthermore, in some embodiments, package-level interconnects 706 are provided on or over a front-side of IC die 702 (i.e., over front-side metallization layers 704) and package-level cooling structure 788 is provided on or over a back-side of IC die 702.

In IC system 700, IC die 702 includes die-level, active-cooling as provided by die-level microchannels 777. Die-level microchannels 777 are to convey a heat transfer fluid therein to remove heat from IC die 702. The heat transfer fluid may be any suitable liquid or gas. In some embodiments, the heat transfer fluid is liquid nitrogen operable to lower the temperature of IC die 702 to a temperature at or below about −196° C. In some embodiments, the heat transfer fluid is a fluid with a cryogenic temperature operating window (e.g., about −180° C. to about −70° C.). In some embodiments, the heat transfer fluid is one of helium-3, helium-4, hydrogen, neon, air, fluorine, argon, oxygen, or methane.

As used herein, the term “microchannels” indicates a channel to convey a heat transfer fluid with the multiple microchannels providing discrete separate channels or a network of channels. Notably, the plural microchannels does not indicate separate channel networks are needed. Such die-level microchannels 777 may be provided in any pattern in the x-y plane such as serpentine patterns, patterns of multiple parallel die-level microchannels 777, or the like. Die-level microchannels 777 couple to a heat exchanger (not shown) that removes heat from and cools the heat transfer fluid before re-introduction to die-level microchannels 777. The flow of fluid within die-level microchannels 777 may be provided by a pump or other fluid flow device. The operation of the heat exchanger, pump, etc. may be controlled by a controller.

In the illustrated embodiment, die-level microchannels 777 are implemented at metallization level M12. In other embodiments, die-level microchannels 777 are implemented over metallization level M12. Die-level microchannels 777 may be formed using any suitable technique or techniques such as patterning and etch techniques to form the void structures of die-level microchannels 777 and passivation or deposition techniques to form a cover structure 778 to enclose the void structures. As shown, in some embodiments, the die-level, active-cooling structure of IC system 700 includes a number of die-level microchannels 777 in IC die 702 and over a number of front-side metallization layers 704. As discussed, die-level microchannels 777 are to convey a heat transfer fluid therein. In some embodiments, a metallization feature 779 of metallization layer M12 is laterally adjacent to die-level microchannels 777. For example, metallization feature 779 may couple to a package-level interconnect structure (not shown) for signal routing for IC die 702. In some embodiments, a passive heat removal device such as a heat sink or the like may be used instead of or in addition to package-level cooling structure 788. In some embodiments, package-level cooling structure 788 is not deployed in IC system 700.

As used herein, the term “metallization layer” describes layers with interconnections or wires that provide electrical routing, generally formed of metal or other electrically and thermally conductive material. Adjacent metallization layers may be formed of different materials and by different methods. Adjacent metallization layers, such as metallization interconnects 751, are interconnected by vias, such as vias 752, that may be characterized as part of the metallization layers or between the metallization layers. As shown, in some embodiments, front-side metallization layers 704 are formed over and immediately adjacent transistors. The back-side is then the opposite side, which may be exposed during processing by attaching the front-side to a carrier wafer and exposing the back-side (e.g., by back-side grind or etch operations) as known in the art.

In the illustrated example, front-side metallization layers 704 include M0, V0, M1, M2/V1, M3/V2, M4/V3, and M4-M12. However, front-side metallization layers 704 may include any number of metallization layers such as eight or more metallization layers. Similarly, back-side metallization layers 705 include BM0, BM1, BM2, and BM3. However, back-side metallization layers 705 may include any number of metallization layers such as two to five metallization layers. Front-side metallization layers 704 and back-side metallization layers 705 are embedded within dielectric materials. Furthermore, optional metal-insulator-metal (MIM) devices such as diode devices may be provided within back-side metallization layers 705. Other devices such as capacitive memory devices may be provided within front-side metallization layers 704 and/or back-side metallization layers 705.

IC system 700 includes package-level active-cooling structure 788 having package-level microchannels 789. Package-level microchannels 789 are to convey a heat transfer fluid therein to remove heat from IC die 702. The heat transfer fluid may be any suitable liquid or gas as discussed with respect to die-level microchannels 777. Package-level microchannels 789 may be provided in any pattern in the x-y plane such as serpentine patterns, patterns of multiple parallel package-level microchannels 789, etc. Package-level microchannels 789 couple to a heat exchanger (not shown) that removes heat from and cools the heat transfer fluid before re-introduction to package-level microchannels 789. The flow of fluid within package-level microchannels 789 may be provided by a pump or other fluid-flow device. The operation of the heat exchanger, pump, etc. may be controlled by a controller. In the illustrated embodiment, package-level active-cooling structure 788 is a chiller mounted to IC die 702 such that the chiller has a solid body having microchannels therein to convey a heat transfer fluid.

In some embodiments, the heat-removal fluid deployed in die-level microchannels 777 and package-level active-cooling structure 788 are coupled to the same pump and heat exchanger systems. In such embodiments, the heat removal fluid conveyed in both die-level microchannels 777 and package-level active-cooling structure 788 are the same material. Such embodiments may advantageously provide simplicity. In other embodiments, the heat removal fluids are controlled separately. In such embodiments, the heat removal fluids conveyed by die-level microchannels 777 and package-level active-cooling structure 788 may be the same or they may be different. Such embodiments may advantageously provide improved flexibility.

As discussed, IC system 700 includes IC die 702 and optional die-level and package-level active-cooling structures operable to remove heat from IC die 702 to achieve a very low operating temperature of IC die 702. As used herein, the term “very low operating temperature” indicates a temperature at or below 0° C., although even lower temperatures such as an operating temperature at or below −50° C., an operating temperature at or below −70° C., an operating temperature at or below −100° C., an operating temperature at or below −180° C., or an operating temperature at or below −196° C. may be used. In some embodiments, the operating temperature is in a cryogenic temperature operating window (e.g., about −180° C. to about −70° C.). The active-cooling structure may be provided as a package-level structure (i.e., separable from IC die 702), as a die-level structure (i.e., integral to IC die 702), or both. In some embodiments, IC die 702 is deployed in a cold environment, formed using sufficiently conductive materials, etc. and an active-cooling structure is not used.

FIG. 8 illustrates a view of an example two-phase immersion cooling system 800 for low-temperature operation of an IC die, in accordance with some embodiments. As shown, two-phase immersion cooling system 800 includes a fluid containment structure 801, a low-boiling point liquid 802 within fluid containment structure 801, and a condensation structure 803 at least partially within fluid containment structure 801. As used herein, the term “low-boiling point liquid” indicates a liquid having a boiling point in the very low temperature ranges discussed. In some embodiments, the low-boiling point liquid is one of helium-3, helium-4, hydrogen, neon, air, fluorine, argon, oxygen, or methane.

In operation, a heat generation source 804, such as an IC package including any of IC dies or systems 100, 200, 300, 600, 700 as discussed herein is immersed in low-boiling point liquid 802. In some embodiments, IC dies or systems 100, 200, 300, 600, 700 as deployed in two-phase immersion cooling system 800 do not include additional active cooling structures, although such die-level or package-level active cooling structures may be used in concert with two-phase immersion cooling system 800. In some embodiments, when deployed in two-phase immersion cooling system 800, package-level active-cooling structure 788 is a heat sink, a heat dissipation plate, a porous heat dissipation plate or the like.

Notably, IC die 702 (or IC die 100, 200, 330, 600), is the source of heat in the context of two-phase immersion cooling system 800. For example, IC die 702 may be packaged and mounted on electronics substrate 805. Electronic substrate 805 may be coupled to a power supply (not shown) and may be partially or completely submerged in low-boiling point liquid 802.

In operation, the heat produced by heat generation source 804 vaporizes low-boiling point liquid 802 as shown in vapor or gas state as bubbles 806, which may collect, due to gravitational forces, above low-boiling point liquid 802 as a vapor portion 807 within fluid containment structure 801. Condensation structure 803 may extend through vapor portion 807. In some embodiments, condensation structure 803 is a heat exchanger having a number of tubes 808 with a cooling fluid (i.e., a fluid colder than the condensation point of vapor portion 807) shown by arrows 809 that may flow through tubes 808 to condense vapor portion 807 back to low-boiling point liquid 802. In the IC system of FIG. 8, package-level active-cooling structure 788 includes a passive cooling structure such as a heat sink for immersion in low-boiling point liquid 802.

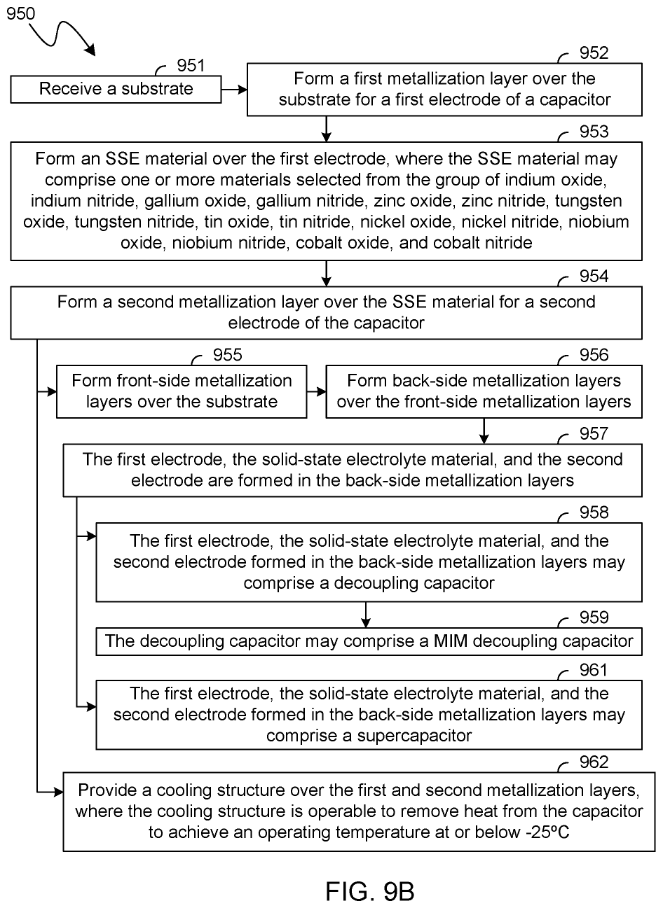

FIG. 9A illustrates various processes or methods 900 for forming SSE capacitors on an IC die, in accordance with some embodiments. FIG. 9A show methods 900 that include operations 901-912. Some operations shown in FIG. 9A are optional. FIG. 9A shows an example sequence, but the operations can be done in other sequences as well, and some operations may be omitted. Some operations can also be performed multiple times before other operations are performed. Some operations may be included within other operations. Methods 900 generally entail forming metallization structures for capacitor electrodes and forming SSE material between the electrodes.

In operation 901, a substrate is received. The substrate is a planar platform and may already include dielectric and metallization structures. The substrate may be one of many layers in an IC die, and may itself have many layers. The substrate may be above other layers in the IC die (all or of a portion of which may be subsequently removed in back-side metallization contexts), and other layers may subsequently be formed in or over the substrate. In some embodiments, SSE capacitors will be formed on a frontside of the substrate. In some embodiments, SSE capacitors will be formed on a backside. In some embodiments, SSE capacitors will be formed on both sides.

The substrate may include any suitable material or materials. Any suitable semiconductor or other material can be used. Transistors in the IC die may be of the same material as the substrate or, e.g., deposited on the substrate. The substrate may include a semiconductor material that transistors can be formed out of and on, including a crystalline material. In some examples, the substrate may include monocrystalline silicon (Si), germanium (Ge), silicon germanium (SiGe), a III-V alloy material (e.g., gallium arsenide (GaAs)), a silicon carbide (SiC), a sapphire (Al₂O₃), or any combination thereof. In some embodiments, the substrate includes crystalline silicon and subsequent components are also silicon.

In operation 902, front-side metallization layers are formed over the substrate. The front-side metallization layers need not be formed before, e.g., other layers of the IC die. Forming the front-side metallization layers and other layers of the IC die may include forming transistors, resistors, and interconnections, e.g., between them and with external structures, including power, signal, data, ground, etc. lines. At least some of these structures may be conventional and known methods may be used.

Transistors in the front-side metallization layers can be formed from the same material as the substrate or, e.g., deposited on the substrate. In some embodiments, the substrate is crystalline silicon and transistors in the front-side metallization layers are formed by etching back the substrate to form transistor structures, e.g., non-planar structures, such as fins for access transistor channels. In some embodiments, transistors comprise polycrystalline silicon, which may be deposited over other materials. Other semiconductor materials may be deposited as well, on the substrate or over other structures on the substrate. Such semiconductor materials can be any material suitable for forming a transistor channel, e.g., for an access transistor, but some materials will be preferred for their manufacturing properties, e.g., the capability to be deposited easily, in a well-controlled manner, and in thin layers.

Forming the front-side metallization layers may include forming ultrathin structures, such as nanowires, nanoribbons, or nanosheets, for transistor channels. In some embodiments, one or a few monolayers of semiconductor materials are deposited over the substrate or other structures. In some embodiments, less than 2 nm of semiconductor material is deposited as a film. In some embodiments, a transition-metal dichalcogenide (TMD) material is deposited to form access transistors. TMDs can be 2D materials, e.g., forming monolayers of semiconductor materials. 2D materials may be deposited on structures, such as backbone features, deposited on the substrate.

In operation 903, back-side metallization layers are formed over the front-side metallization layers. The back-side metallization layers need not be formed before, e.g., other layers of the IC die. Forming the back-side metallization layers and other layers of the IC die may include forming transistors, resistors, and interconnections, e.g., between them and with external structures, including power, signal, data, ground, etc. lines. At least some of these structures may be conventional and known methods may be used.

Transistors in the back-side metallization layers can be formed from the same material as the substrate or, e.g., deposited on the substrate. In some embodiments, the substrate is crystalline silicon and transistors in the back-side metallization layers are formed by etching back the substrate to form transistor structures, e.g., non-planar structures, such as fins for access transistor channels. In some embodiments, transistors comprise polycrystalline silicon, which may be deposited over other materials. Other semiconductor materials may be deposited as well, on the substrate or over other structures on the substrate. Such semiconductor materials can be any material suitable for forming a transistor channel, e.g., for an access transistor, but some materials will be preferred for their manufacturing properties, e.g., the capability to be deposited easily, in a well-controlled manner, and in thin layers.

Forming the back-side metallization layers may include forming ultrathin structures, such as nanowires, nanoribbons, or nanosheets, for transistor channels. In some embodiments, one or a few monolayers of semiconductor materials are deposited over the substrate or other structures. In some embodiments, less than 2 nm of semiconductor material is deposited as a film. In some embodiments, a transition-metal dichalcogenide (TMD) material is deposited to form access transistors. TMDs can be 2D materials, e.g., forming monolayers of semiconductor materials. 2D materials may be deposited on structures, such as backbone features, deposited on the substrate.

The methods for forming transistors may vary with transistor function. TFTs for use as pull-up transistors may be formed as parasitic devices deposited over other structures in some layers. In some embodiments, forming transistors includes depositing amorphous or polycrystalline metal oxides. In some embodiments, a thin, metal-oxide film is deposited that may be semiconducting substantially as-deposited, and/or following some subsequent activation process, such as a thermal anneal.

Other structures, e.g., resistors and metallization, may also be deposited or otherwise formed from such materials, and such forming may be done throughout the forming operations of transistors and other structures. Pull-up resistors may be formed from the substrate material or, e.g., by depositing polycrystalline silicon or other material over the substrate. Other structures, e.g., access transistor gate electrodes, may be formed such that convenient connections can be made to associated structures in the first layer. Metallization may be formed before and after, and interleaved throughout, the forming of other structures.

In operation 904, a first electrode of a capacitor is formed in the back-side metallization layers. In operation 905, a second electrode of the capacitor is formed in the back-side metallization layers. In operation 906, an SSE material is formed between the first electrode and the second electrode of the capacitor in the back-side metallization layers. In some embodiments, the SSE material may comprise an inorganic SE material at box 907. In some embodiments, the inorganic SE material may comprise one or more materials selected from the group of indium oxide, indium nitride, gallium oxide, gallium nitride, zinc oxide, zinc nitride, tungsten oxide, tungsten nitride, tin oxide, tin nitride, nickel oxide, nickel nitride, niobium oxide, niobium nitride, cobalt oxide, and cobalt nitride at box 908.

In some embodiments, the capacitor in the back-side metallization layers may comprise a decoupling capacitor at box 909. For example, the decoupling capacitor may comprise a MIM decoupling capacitor at box 910. In some embodiments, the capacitor in the back-side layers may comprise a supercapacitor at box 911. In operation 912, a cooling structure is provided over the front-side and back-side metallization layers, wherein the cooling structure is operable to remove heat from the capacitor to achieve an operating temperature at or below −25° C.

FIG. 9B illustrates various processes or methods 950 for forming SSE capacitors on an IC die, in accordance with some embodiments. FIG. 9B show methods 950 that include operations 951-962. Some operations shown in FIG. 9B are optional. FIG. 9B shows an example sequence, but the operations can be done in other sequences as well, and some operations may be omitted. Some operations can also be performed multiple times before other operations are performed. Some operations may be included within other operations. Methods 950 generally entail forming metallization structures for capacitor electrodes and forming SSE material between the electrodes.

In operation 951, a substrate is received. The substrate is a planar platform and may already include dielectric and metallization structures. The substrate may be one of many layers in an IC die, and may itself have many layers. The substrate may be above other layers in the IC die (all or of a portion of which may be subsequently removed in back-side metallization contexts), and other layers may subsequently be formed in or over the substrate. In some embodiments, SSE capacitors will be formed on a frontside of the substrate. In some embodiments, SSE capacitors will be formed on a backside. In some embodiments, SSE capacitors will be formed on both sides.

The substrate may include any suitable material or materials. Any suitable semiconductor or other material can be used. Transistors in the IC die may be of the same material as the substrate or, e.g., deposited on the substrate. The substrate may include a semiconductor material that transistors can be formed out of and on, including a crystalline material. In some examples, the substrate may include monocrystalline silicon (Si), germanium (Ge), silicon germanium (SiGe), a III-V alloy material (e.g., gallium arsenide (GaAs)), a silicon carbide (SiC), a sapphire (Al₂O₃), or any combination thereof. In some embodiments, the substrate includes crystalline silicon and subsequent components are also silicon.

In operation 952, a first metallization layer is formed over the substrate for a first electrode of a capacitor. The first metallization layer need not be formed before, e.g., other layers of the IC die. The first metallization layer may be anywhere in the substrate including, for example, front-side metallization layers or back-side metallization layers. Forming the front-side metallization layers, the back-side metallization layers, and other layers of the IC die may include forming transistors, resistors, and interconnections, e.g., between them and with external structures, including power, signal, data, ground, etc. lines. At least some of these structures may be conventional and known methods may be used.

Transistors in the substrate can be formed from the same material as the substrate or, e.g., deposited on the substrate. In some embodiments, the substrate is crystalline silicon and transistors in the layers of the substrate are formed by etching back the substrate to form transistor structures, e.g., non-planar structures, such as fins for access transistor channels. In some embodiments, transistors comprise polycrystalline silicon, which may be deposited over other materials. Other semiconductor materials may be deposited as well, on the substrate or over other structures on the substrate. Such semiconductor materials can be any material suitable for forming a transistor channel, e.g., for an access transistor, but some materials will be preferred for their manufacturing properties, e.g., the capability to be deposited easily, in a well-controlled manner, and in thin layers.

Forming the metallization layers may include forming ultrathin structures, such as nanowires, nanoribbons, or nanosheets, for transistor channels. In some embodiments, one or a few monolayers of semiconductor materials are deposited over the substrate or other structures. In some embodiments, less than 2 nm of semiconductor material is deposited as a film. In some embodiments, a transition-metal dichalcogenide (TMD) material is deposited to form access transistors. TMDs can be 2D materials, e.g., forming monolayers of semiconductor materials. 2D materials may be deposited on structures, such as backbone features, deposited on the substrate.

The methods for forming transistors may vary with transistor function. TFTs for use as pull-up transistors may be formed as parasitic devices deposited over other structures in some layers. In some embodiments, forming transistors includes depositing amorphous or polycrystalline metal oxides. In some embodiments, a thin, metal-oxide film is deposited that may be semiconducting substantially as-deposited, and/or following some subsequent activation process, such as a thermal anneal.

Other structures, e.g., resistors and metallization, may also be deposited or otherwise formed from such materials, and such forming may be done throughout the forming operations of transistors and other structures. Pull-up resistors may be formed from the substrate material or, e.g., by depositing polycrystalline silicon or other material over the substrate. Other structures, e.g., access transistor gate electrodes, may be formed such that convenient connections can be made to associated structures in the first layer. Metallization may be formed before and after, and interleaved throughout, the forming of other structures.

In operation 953, an SSE material is formed over the first electrode, where the SSE material may comprise one or more materials selected from the group of indium oxide, indium nitride, gallium oxide, gallium nitride, zinc oxide, zinc nitride, tungsten oxide, tungsten nitride, tin oxide, tin nitride, nickel oxide, nickel nitride, niobium oxide, niobium nitride, cobalt oxide, and cobalt nitride. In operation 954, a second metallization layer is formed over the SSE material for a second electrode of the capacitor.

In operation 955, front-side metallization layers are formed over the substrate. In operation 956, back-side metallization layers are formed over the front-side metallization layers. In operation 957, the first electrode, the solid-state electrolyte material, and the second electrode are formed in the back-side metallization layers. In some embodiments, the first electrode, the solid-state electrolyte material, and the second electrode formed in the back-side metallization layers may comprise a decoupling capacitor at box 958. For example, the decoupling capacitor may comprise a MIM decoupling capacitor at box 959. In some embodiments, the first electrode, the solid-state electrolyte material, and the second electrode formed in the back-side metallization layers may comprise a supercapacitor at box 961. In operation 962, a cooling structure is provided over the first and second metallization layers, wherein the cooling structure is operable to remove heat from the capacitor to achieve an operating temperature at or below −25° C.

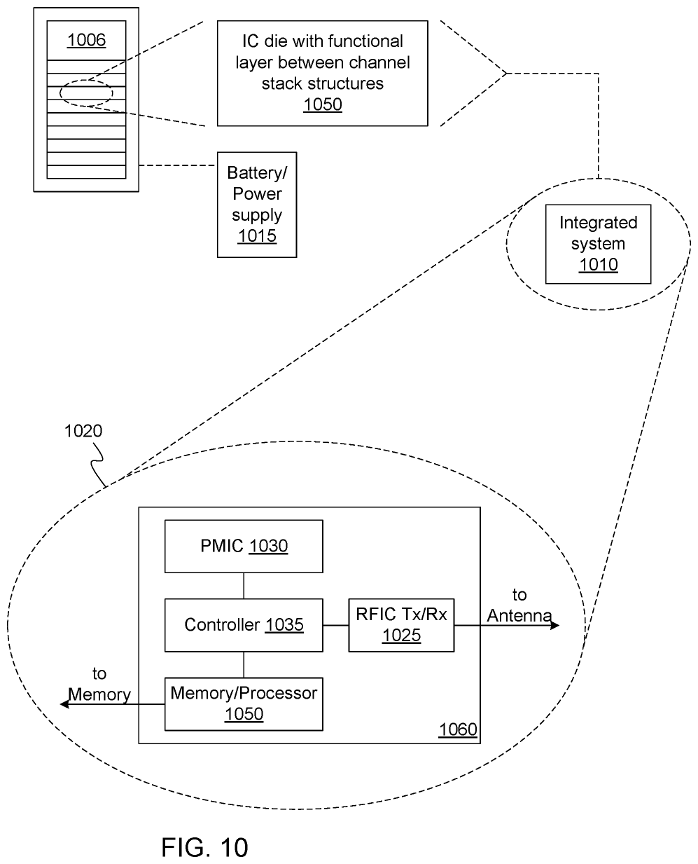

FIG. 10 illustrates a diagram of an example data server machine 1006 employing an IC die with SSE capacitors, in accordance with some embodiments. Server machine 1006 may be any commercial server, for example, including any number of high-performance computing platforms disposed within a rack and networked together for electronic data processing, which in the exemplary embodiment includes one or more devices 1050 having SSE capacitors.

Also as shown, server machine 1006 includes a battery and/or power supply 1015 to provide power to devices 1050, and to provide, in some embodiments, power delivery functions such as power regulation. Devices 1050 may be deployed as part of a package-level integrated system 1010. Integrated system 1010 is further illustrated in the expanded view 1020. In the exemplary embodiment, devices 1050 (labeled “Memory/Processor”) includes at least one memory chip (e.g., RAM), and/or at least one processor chip (e.g., a microprocessor, a multi-core microprocessor, or graphics processor, or the like) having the characteristics discussed herein. In an embodiment, device 1050 is a microprocessor including a cache memory. As shown, device 1050 may be a multi-chip module employing one or more IC dies with SSE capacitors, as discussed herein. Device 1050 may be further coupled to (e.g., communicatively coupled to) a board, an interposer, or a substrate 1060 along with, one or more of a power management IC (PMIC) 1030, RF (wireless) IC (RFIC) 1025, including a wideband RF (wireless) transmitter and/or receiver (TX/RX) (e.g., including a digital baseband and an analog front end module further comprises a power amplifier on a transmit path and a low noise amplifier on a receive path), and a controller 1035 thereof. In some embodiments, RFIC 1025, PMIC 1030, controller 1035, and device 1050 include IC dies having SSE capacitors on substrate 1060 in a multi-chip module.

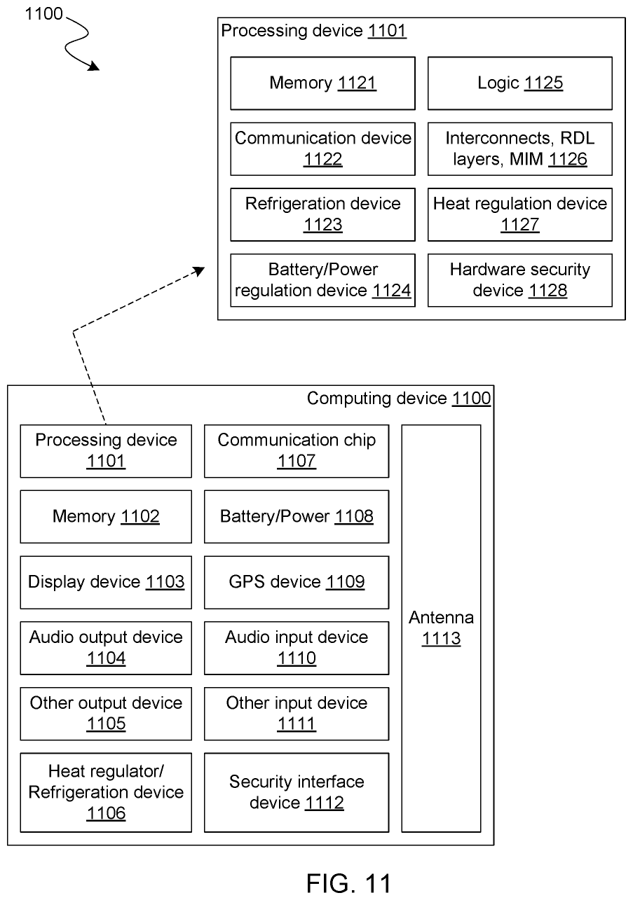

FIG. 11 is a block diagram of an example computing device 1100, in accordance with some embodiments. For example, one or more components of computing device 1100 may include any of the devices or structures discussed herein. A number of components are illustrated in FIG. 11 as being included in computing device 1100, but any one or more of these components may be omitted or duplicated, as suitable for the application. In some embodiments, some or all of the components included in computing device 1100 may be attached to one or more printed circuit boards (e.g., a motherboard). In some embodiments, various ones of these components may be fabricated onto a single system-on-a-chip (SoC) die. Additionally, in various embodiments, computing device 1100 may not include one or more of the components illustrated in FIG. 11, but computing device 1100 may include interface circuitry for coupling to the one or more components. For example, computing device 1100 may not include a display device 1103, but may include display device interface circuitry (e.g., a connector and driver circuitry) to which display device 1103 may be coupled. In another set of examples, computing device 1100 may not include an audio output device 1104, other output device 1105, global positioning system (GPS) device 1109, audio input device 1110, or other input device 1111, but may include audio output device interface circuitry, other output device interface circuitry, GPS device interface circuitry, audio input device interface circuitry, audio input device interface circuitry, to which audio output device 1104, other output device 1105, GPS device 1109, audio input device 1110, or other input device 1111 may be coupled.

Computing device 1100 may include a processing device 1101 (e.g., one or more processing devices). As used herein, the term “processing device” or “processor” indicates a device that processes electronic data from registers and/or memory to transform that electronic data into other electronic data that may be stored in registers and/or memory. Processing device 1101 may include a memory 1121, a communication device 1122, a refrigeration device 1123, a battery/power regulation device 1124, logic 1125, interconnects 1126 (i.e., optionally including redistribution layers (RDL) or metal-insulator-metal (MIM) devices), a heat regulation device 1127, and a hardware security device 1128.

Processing device 1101 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1100 may include a memory 1102, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1102 includes memory that shares a die with processing device 1101. This memory may be used as cache memory and may include embedded dynamic random-access memory (eDRAM) or spin transfer torque magnetic random-access memory (STT-M RAM).

Computing device 1100 may include a heat regulation/refrigeration device 1106. Heat regulation/refrigeration device 1106 may maintain processing device 1101 (and/or other components of computing device 1100) at a predetermined low temperature during operation. This predetermined low temperature may be any temperature discussed herein.

In some embodiments, computing device 1100 may include a communication chip 1107 (e.g., one or more communication chips). For example, the communication chip 1107 may be configured for managing wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1107 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1107 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1107 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1107 may operate in accordance with other wireless protocols in other embodiments. Computing device 1100 may include an antenna 1113 to facilitate wireless communications and/or to receive other wireless communications (such as AM or FM radio transmissions).

In some embodiments, communication chip 1107 may manage wired communications, such as electrical, optical, or any other suitable communication protocols (e.g., the Ethernet). As noted above, communication chip 1107 may include multiple communication chips. For instance, a first communication chip 1107 may be dedicated to shorter-range wireless communications such as Wi-Fi or Bluetooth, and a second communication chip 1107 may be dedicated to longer-range wireless communications such as GPS, EDGE, GPRS, CDMA, WiMAX, LTE, EV-DO, or others. In some embodiments, a first communication chip 1107 may be dedicated to wireless communications, and a second communication chip 1107 may be dedicated to wired communications.

Computing device 1100 may include battery/power circuitry 1108. Battery/power circuitry 1108 may include one or more energy storage devices (e.g., batteries or capacitors) and/or circuitry for coupling components of computing device 1100 to an energy source separate from computing device 1100 (e.g., AC line power).

Computing device 1100 may include a display device 1103 (or corresponding interface circuitry, as discussed above). Display device 1103 may include any visual indicators, such as a heads-up display, a computer monitor, a projector, a touchscreen display, a liquid crystal display (LCD), a light-emitting diode display, or a flat panel display, for example.

Computing device 1100 may include an audio output device 1104 (or corresponding interface circuitry, as discussed above). Audio output device 1104 may include any device that generates an audible indicator, such as speakers, headsets, or earbuds, for example.

Computing device 1100 may include an audio input device 1110 (or corresponding interface circuitry, as discussed above). Audio input device 1110 may include any device that generates a signal representative of a sound, such as microphones, microphone arrays, or digital instruments (e.g., instruments having a musical instrument digital interface (MIDI) output).

Computing device 1100 may include a GPS device 1109 (or corresponding interface circuitry, as discussed above). GPS device 1109 may be in communication with a satellite-based system and may receive a location of computing device 1100, as known in the art.

Computing device 1100 may include other output device 1105 (or corresponding interface circuitry, as discussed above). Examples of the other output device 1105 may include an audio codec, a video codec, a printer, a wired or wireless transmitter for providing information to other devices, or an additional storage device.

Computing device 1100 may include other input device 1111 (or corresponding interface circuitry, as discussed above). Examples of the other input device 1111 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1100 may include a security interface device 1112. Security interface device 1112 may include any device that provides security measures for computing device 1100 such as intrusion detection, biometric validation, security encode or decode, access list management, malware detection, or spyware detection.

Computing device 1100, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-11. The subject matter may be applied to other deposition applications, as well as any appropriate manufacturing application, as will be understood to those skilled in the art.

The following examples pertain to further embodiments, and specifics in the examples may be used anywhere in one or more embodiments.

Example 1 includes an IC die, comprising front-side layers, back-side layers coupled to the front-side layers, and a capacitor in the back-side layers, the capacitor comprising a first electrode, a second electrode, and SSE material disposed between the first electrode and the second electrode.

Example 2 includes the IC die of Example 1, wherein the SSE material comprises an inorganic SE material.

Example 3 includes the IC die of Example 2, wherein the inorganic SE material comprises one or more materials selected from the group of indium oxide, indium nitride, gallium oxide, gallium nitride, zinc oxide, zinc nitride, tungsten oxide, tungsten nitride, tin oxide, tin nitride, nickel oxide, nickel nitride, niobium oxide, niobium nitride, cobalt oxide, and cobalt nitride.

Example 4 includes the IC die of any of Examples 1 to 3, wherein the capacitor in the back-side layers comprises a decoupling capacitor.

Example 5 includes the IC die of Example 4, wherein the decoupling capacitor comprises a MIM decoupling capacitor.

Example 6 includes the IC die of any of Examples 1 to 5, wherein the capacitor in the back-side layers comprises a supercapacitor.

Example 7. An IC die, comprising a plurality of capacitor devices, wherein at least one capacitor of the plurality of capacitor devices comprises a first electrode, a second electrode, and material (e.g., SSE material) disposed between the first electrode and the second electrode, wherein the material comprises one or more materials selected from the group of indium oxide, indium nitride, gallium oxide, gallium nitride, zinc oxide, zinc nitride, tungsten oxide, tungsten nitride, tin oxide, tin nitride, nickel oxide, nickel nitride, niobium oxide, niobium nitride, cobalt oxide, and cobalt nitride.

Example 8 includes the IC die of Example 7, further comprising front-side layers, and back-side layers coupled to the front-side layers, wherein the at least one capacitor is in the back-side layers.

Example 9 includes the IC die of Example 8, wherein the at least one capacitor formed in the back-side layers comprises a decoupling capacitor.

Example 10 includes the IC die of Example 9, wherein the decoupling capacitor comprises a MIM decoupling capacitor.

Example 11 includes the IC die of any of Examples 8 to 10, wherein the at least one capacitor in the back-side layers comprises a supercapacitor.

Example 12 includes a system, comprising a substrate, a power supply, and an IC die attached to the substrate and coupled to the power supply, the IC die comprising front-side layers, back-side layers coupled to the front-side layers, and a capacitor in the back-side layers, the capacitor comprising a first electrode, a second electrode, and SSE material disposed between the first electrode and the second electrode.

Example 13 includes the system of Example 12, wherein the SSE material comprises an inorganic SE material.

Example 14 includes the system of Example 13, wherein the inorganic SE material comprises one or more materials selected from the group of indium oxide, indium nitride, gallium oxide, gallium nitride, zinc oxide, zinc nitride, tungsten oxide, tungsten nitride, tin oxide, tin nitride, nickel oxide, nickel nitride, niobium oxide, niobium nitride, cobalt oxide, and cobalt nitride.

Example 15 includes the system of any of Examples 12 to 14, wherein the capacitor in the back-side layers comprises a decoupling capacitor.

Example 16 includes the system of Example 15, wherein the decoupling capacitor comprises a MIM decoupling capacitor.

Example 17 includes the system of any of Examples 12 to 15, wherein the capacitor in the back-side layers comprises a supercapacitor.

Example 18 includes the system of any of Examples 12 to 17, further comprising a cooling structure operable to remove heat from the IC die to achieve an operating temperature at or below −25° C.

Example 19 includes the system of Example 18, wherein the IC die comprises a plurality of metallization layers over a front side of the plurality of capacitor devices, the metallization layers to provide signal routing for the plurality of capacitor devices, and wherein the cooling structure is over the plurality of metallization layers.

Example 20 includes the system of Example 19, wherein the cooling structure comprises a plurality of microchannels in the IC die and over the plurality of metallization layers, the microchannels to convey a heat transfer fluid therein.

Example 21 includes the system of Example 20, wherein the cooling structure further comprises a chiller mounted to the IC die over the microchannels, the chiller comprising one of a solid body comprising second microchannels to convey a second heat transfer fluid therein or a heat sink for immersion in a low-boiling point liquid.

Example 22 includes the system of any of Examples 18 to 21, wherein the cooling structure is to convey liquid nitrogen to achieve an operating temperature at or below about −196° C.

Example 23 includes a method, comprising receiving a substrate, forming front-side metallization layers over the substrate, forming back-side metallization layers over the front-side metallization layers, forming a first electrode of a capacitor in the back-side metallization layers, forming a second electrode of the capacitor in the back-side metallization layers, and forming a SSE material between the first electrode and the second electrode of the capacitor in the back-side metallization layers.

Example 24 includes the method of Example 23, wherein the SSE material comprises an inorganic SE material.

Example 25 includes the method of Example 24, wherein the inorganic SE material comprises one or more materials selected from the group of indium oxide, indium nitride, gallium oxide, gallium nitride, zinc oxide, zinc nitride, tungsten oxide, tungsten nitride, tin oxide, tin nitride, nickel oxide, nickel nitride, niobium oxide, niobium nitride, cobalt oxide, and cobalt nitride.

Example 26 includes the method of any of Examples 23 to 25, wherein the capacitor in the back-side metallization layers comprises a decoupling capacitor.

Example 27 includes the method of Example 26, wherein the decoupling capacitor comprises a MIM decoupling capacitor.

Example 28 includes the method of any of Examples 23 to 27, wherein the capacitor in the back-side layers comprises a supercapacitor.

Example 29 includes the method of any of Examples 23 to 28, further comprising providing a cooling structure over the front-side and back-side metallization layers, wherein the cooling structure is operable to remove heat from the capacitor to achieve an operating temperature at or below −25° C.

Example 30 includes a method, comprising receiving a substrate, forming a first metallization layer over the substrate for a first electrode of a capacitor, forming a SSE material over the first electrode, and forming a second metallization layer over the SSE material for a second electrode of the capacitor, wherein the SSE material comprises one or more materials selected from the group of indium oxide, indium nitride, gallium oxide, gallium nitride, zinc oxide, zinc nitride, tungsten oxide, tungsten nitride, tin oxide, tin nitride, nickel oxide, nickel nitride, niobium oxide, niobium nitride, cobalt oxide, and cobalt nitride.

Example 31 includes the method of Example 30, further comprising forming front-side metallization layers over the substrate, forming back-side metallization layers over the front-side metallization layers, wherein the first electrode, the SSE material, and the second electrode are formed in the back-side metallization layers.

Example 32 includes the method of Example 31, wherein the first electrode, the SSE material, and the second electrode formed in the back-side metallization layers comprises a decoupling capacitor.

Example 33 includes the method of Example 32, wherein the decoupling capacitor comprises a MIM decoupling capacitor.

Example 34 includes the method of any of Examples 31 to 33, wherein the first electrode, the SSE material, and the second electrode formed in the back-side metallization layers comprises a supercapacitor.

Example 35 includes the method of any of Examples 30 to 34, further comprising providing a cooling structure over the first and second metallization layers, wherein the cooling structure is operable to remove heat from the capacitor to achieve an operating temperature at or below −25° C.

Example 36 includes an apparatus, comprising means for receiving a substrate, means for forming front-side metallization layers over the substrate, means for forming back-side metallization layers over the front-side metallization layers, means for forming a first electrode of a capacitor in the back-side metallization layers, means for forming a second electrode of the capacitor in the back-side metallization layers, and means for forming a SSE material between the first electrode and the second electrode of the capacitor in the back-side metallization layers.

Example 37 includes the apparatus of Example 36, wherein the SSE material comprises an inorganic SE material.

Example 38 includes the apparatus of Example 37, wherein the inorganic SE material comprises one or more materials selected from the group of indium oxide, indium nitride, gallium oxide, gallium nitride, zinc oxide, zinc nitride, tungsten oxide, tungsten nitride, tin oxide, tin nitride, nickel oxide, nickel nitride, niobium oxide, niobium nitride, cobalt oxide, and cobalt nitride.

Example 39 includes the apparatus of any of Examples 36 to 38, wherein the capacitor in the back-side metallization layers comprises a decoupling capacitor.

Example 40 includes the apparatus of Example 39, wherein the decoupling capacitor comprises a MIM decoupling capacitor.

Example 41 includes the apparatus of any of Examples 36 to 40, wherein the capacitor in the back-side layers comprises a supercapacitor.

Example 42 includes the apparatus of any of Examples 36 to 41, further comprising means for providing a cooling structure over the front-side and back-side metallization layers, wherein the cooling structure is operable to remove heat from the capacitor to achieve an operating temperature at or below −25° C.

Example 43 includes an apparatus, comprising means for receiving a substrate, means for forming a first metallization layer over the substrate for a first electrode of a capacitor, means for forming a SSE material over the first electrode, and means for forming a second metallization layer over the SSE material for a second electrode of the capacitor, wherein the SSE material comprises one or more materials selected from the group of indium oxide, indium nitride, gallium oxide, gallium nitride, zinc oxide, zinc nitride, tungsten oxide, tungsten nitride, tin oxide, tin nitride, nickel oxide, nickel nitride, niobium oxide, niobium nitride, cobalt oxide, and cobalt nitride.

Example 44 includes the apparatus of Example 43, further comprising means for forming front-side metallization layers over the substrate, means for forming back-side metallization layers over the front-side metallization layers, wherein the first electrode, the SSE material, and the second electrode are formed in the back-side metallization layers.

Example 45 includes the apparatus of Example 44, wherein the first electrode, the SSE material, and the second electrode formed in the back-side metallization layers comprises a decoupling capacitor.

Example 46 includes the apparatus of Example 45, wherein the decoupling capacitor comprises a MIM decoupling capacitor.

Example 47 includes the apparatus of any of Examples 44 to 46, wherein the first electrode, the SSE material, and the second electrode formed in the back-side metallization layers comprises a supercapacitor.

Example 48 includes the apparatus of any of Examples 43 to 47, further comprising means for providing a cooling structure over the first and second metallization layers, wherein the cooling structure is operable to remove heat from the capacitor to achieve an operating temperature at or below −25° C.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An integrated circuit (IC) die, comprising:
front-side layers;
back-side layers coupled to the front-side layers; and
a capacitor in the back-side layers, the capacitor comprising:
a first electrode,
a second electrode, and
solid-state electrolyte material disposed between the first electrode and the second electrode.

2. The IC die of claim 1, wherein the solid-state electrolyte material comprises an inorganic solid electrolyte material.

3. The IC die of claim 2, wherein the inorganic solid electrolyte material comprises one or more materials selected from the group of indium oxide, indium nitride, gallium oxide, gallium nitride, zinc oxide, zinc nitride, tungsten oxide, tungsten nitride, tin oxide, tin nitride, nickel oxide, nickel nitride, niobium oxide, niobium nitride, cobalt oxide, and cobalt nitride.

4. The IC die of claim 1, wherein the capacitor in the back-side layers comprises a decoupling capacitor.

5. The IC die of claim 4, wherein the decoupling capacitor comprises a metal-insulator-metal (MIM) decoupling capacitor.

6. The IC die of claim 1, wherein the capacitor in the back-side layers comprises a supercapacitor.

7. An integrated circuit (IC) die, comprising a plurality of capacitor devices, wherein at least one capacitor of the plurality of capacitor devices comprises:
a first electrode;
a second electrode; and
material disposed between the first electrode and the second electrode, wherein the material comprises one or more materials selected from the group of indium oxide, indium nitride, gallium oxide, gallium nitride, zinc oxide, zinc nitride, tungsten oxide, tungsten nitride, tin oxide, tin nitride, nickel oxide, nickel nitride, niobium oxide, niobium nitride, cobalt oxide, and cobalt nitride.

8. The IC die of claim 7, further comprising:
front-side layers; and
back-side layers coupled to the front-side layers, wherein the at least one capacitor is in the back-side layers.

9. The IC die of claim 8, wherein the at least one capacitor formed in the back-side layers comprises a decoupling capacitor.

10. The IC die of claim 9, wherein the decoupling capacitor comprises a metal-insulator-metal (MIM) decoupling capacitor.

11. The IC die of claim 8, wherein the at least one capacitor in the back-side layers comprises a supercapacitor.

12. A system, comprising:
a substrate;
a power supply; and
an integrated circuit (IC) die attached to the substrate and coupled to the power supply, the IC die comprising front-side layers, back-side layers coupled to the front-side layers, and a capacitor in the back-side layers, the capacitor comprising:
a first electrode,
a second electrode, and
solid-state electrolyte material disposed between the first electrode and the second electrode.

13. The system of claim 12, wherein the solid-state electrolyte material comprises an inorganic solid electrolyte material.

14. The system of claim 13, wherein the inorganic solid electrolyte material comprises one or more materials selected from the group of indium oxide, indium nitride, gallium oxide, gallium nitride, zinc oxide, zinc nitride, tungsten oxide, tungsten nitride, tin oxide, tin nitride, nickel oxide, nickel nitride, niobium oxide, niobium nitride, cobalt oxide, and cobalt nitride.

15. The system of claim 12, wherein the capacitor in the back-side layers comprises a decoupling capacitor.

16. The system of claim 15, wherein the decoupling capacitor comprises a metal-insulator-metal (MIM) decoupling capacitor.

17. The system of claim 12, wherein the capacitor in the back-side layers comprises a supercapacitor.

18. The system of claim 12, further comprising:
a cooling structure operable to remove heat from the IC die to achieve an operating temperature at or below −25° C.

19. The system of claim 18, wherein the IC die comprises a plurality of metallization layers over a front side of the plurality of capacitor devices, the metallization layers to provide signal routing for the plurality of capacitor devices, and wherein the cooling structure is over the plurality of metallization layers.

20. The system of claim 19, wherein the cooling structure comprises a plurality of microchannels in the IC die and over the plurality of metallization layers, the microchannels to convey a heat transfer fluid therein.

21. The system of claim 20, wherein the cooling structure further comprises a chiller mounted to the IC die over the microchannels, the chiller comprising one of a solid body comprising second microchannels to convey a second heat transfer fluid therein or a heat sink for immersion in a low-boiling point liquid.

22. The system of claim 18, wherein the cooling structure is to convey liquid nitrogen to achieve an operating temperature at or below about −196° C.
